(19) United States
(12) Patent Application Publication
(10) Pub. No.: US 2026/0164789 A1
(43) Pub. Date: Jun. 11, 2026

(54) INTEGRATED CIRCUIT INCLUDING FILLER CELL

(71) Applicant: Samsung Electronics Co., Ltd., Suwon-si (KR)

(72) Inventors: Byung Sung Kim, Suwon-si (KR); Seung Choi, Suwon-si (KR)

(21) Appl. No.: 19/246,670

(22) Filed: Jun. 23, 2025

(30) Foreign Application Priority Data
Dec. 5, 2024 (KR) 10-2024-0179693

(51) Int. Cl. H10D 84/90; H10D 89/10

(52) U.S. Cl. CPC H10D 84/974; H10D 84/953; H10D 89/10

(57) ABSTRACT

The present disclosure relates to an integrated circuit having an improved degree of integration. An example integrated circuit comprises a first cell and a second cell each comprising a first active region and a second active region, and a one-pitch dimension filler cell arranged between the first cell and the second cell and adjacent to the first and second cells in a first direction. The filler cell comprises a first gate stack and a second gate stack that are adjacent to each other in the first direction, and a separation structure arranged between the first and second gate stacks. The separation structure at least partially splits the first active region and the second active region.

### CROSS-REFERENCE TO RELATED APPLICATION

This application claims priority under 35 U.S.C. § 119 to Korean Patent Application No. 10-2024-0179693, filed on Dec. 5, 2024, in the Korean Intellectual Property Office, the disclosure of which is incorporated by reference herein in its entirety.

### BACKGROUND

An integrated circuit may be designed based on standard cells. In detail, by placing the standard cells according to data that defines the integrated circuit, and routing the placed standard cells, the layout of the integrated circuit may be generated. These standard cells are predesigned and stored in a cell library.

As semiconductors produced by a semiconductor manufacturing process become more miniaturized, the sizes of patterns within standard cells may decrease, and the sizes of standard cells may decrease.

### SUMMARY

The present disclosure relates to an integrated circuit having a layout with an improved degree of integration.

In addition, the present disclosure is not limited to problems mentioned above, and other problems will be clearly understood by those skilled in the art from the following description.

In general, according to some aspects, an integrated circuit includes a first cell and a second cell each including a first active region and a second active region, and a one-pitch dimension filler cell arranged between the first cell and the second cell and adjacent to the first and second cells in a first direction, wherein the filler cell includes a first gate stack and a second gate stack that are adjacent to each other in the first direction, and a separation structure arranged between the first and second gate stacks, and the separation structure at least partially splits the first active region and the second active region.

In general, according to some aspects, an integrated circuit includes a first cell and a second cell, each including an integrated transistor, a one-pitch dimension filler cell arranged between the first cell and the second cell and adjacent to the first and second cells in a first direction, and a plurality of gate stacks extending in a second direction intersecting with the first direction and spaced apart from each other in the first direction, wherein the filler cell includes two gate stacks that are adjacent to each other among the plurality of gate stacks, and a separation structure arranged between the two gate stacks and extending in the second direction, and a first semiconductor pattern included in the first cell and adjacent to one side wall of the separation structure and a second semiconductor pattern included in the second cell and adjacent to the other side wall opposite to the one side wall of the separation structure are doped with impurities of different conductivity types.

In general, according to some aspects, an integrated circuit includes a filler cell having a one-pitch dimension and including a first side wall and a second side wall opposite to the first side wall, a first cell and a third cell that are adjacent to the first side wall of the filler cell, a second cell adjacent to the second side wall of the filler cell, and a plurality of gate stacks spaced apart from each other in a first direction and extending in a second direction intersecting with the first direction, wherein the filler cell includes two gate stacks that are adjacent to each other among the plurality of gate stacks, and a separation structure arranged between the two gate stacks and extending in the second direction, a height of each of the filler cell and the second cell in the second direction is twice a height of each of the first cell and the third cell in the second direction, the first and third cells include active regions having a first width in the second direction, and the second cell includes first active regions each having the first width in the second direction and a second active region having a second width that is twice the first width.

### BRIEF DESCRIPTION OF THE DRAWINGS

Implementations will be more clearly understood from the following detailed description taken in conjunction with the accompanying drawings.

FIGS. 1 and 2 are conceptual diagrams for explaining logic cells of an example of an integrated circuit device.

FIG. 3 is an integrated circuit layout diagram for explaining an example of an integrated circuit.

FIG. 4 is an example cross-sectional view taken along a line A-A′ of FIG. 3.

FIG. 5 is an integrated circuit layout diagram for explaining an example of an integrated circuit.

FIG. 6 is an integrated circuit layout diagram for explaining an example of an integrated circuit.

FIG. 7 is an integrated circuit layout diagram for explaining an example of an integrated circuit.

FIG. 8 is an integrated circuit layout diagram for explaining an example of an integrated circuit.

FIG. 9 is an integrated circuit layout diagram for explaining an example of an integrated circuit.

FIG. 10 is an integrated circuit layout diagram for explaining an example of an integrated circuit.

FIG. 11 is an integrated circuit layout diagram for explaining an example of an integrated circuit.

### DETAILED DESCRIPTION

Hereinafter, implementations of the present disclosure will be described in detail with reference to the accompanying drawings. The same reference numerals are used to denote the same elements in the drawings, and repeated descriptions thereof will be omitted.

Implementations set forth herein may have various modifications and various forms, and thus, some implementations will be illustrated in the drawings and described in detail in the detailed description. However, this is not intended to limit the present disclosure to particular modes of practice, and it is to be appreciated that all changes, equivalents, and substitutes that do not depart from the spirit and technical scope of the present disclosure are encompassed in the present disclosure. In the description of the implementations, certain detailed explanations of the related art are omitted when it is deemed that they may unnecessarily obscure the essence of the present disclosure.

An integrated circuit according to some implementations may include one or more standard cells arranged in an integrated circuit layout according to predefined rules. The one or more standard cells may be repeatedly used in an integrated circuit design. Therefore, standard cells may be pre-designed according to manufacturing technology and stored in a standard cell library. Integrated circuit designers may retrieve such standard cells, include them in an integrated circuit design, and place them in an integrated circuit layout according to predefined placement rules.

Standard cells may include various basic circuit devices such as inverters, and AND, NAND, OR, XOR, and NOR logic circuits, commonly used in digital circuit design for electronic devices, such as central processing unit (CPU), graphics processing unit (GPU), and system-on-chip (SoC) designs. The standard cells may also include other circuit devices commonly used in circuit blocks, such as flip-flops and latches.

A filler cell may be a designed block of an integrated circuit, which is inserted between two standard cells to comply with integrated circuit design and integrated circuit manufacturing rules. Proper design and arrangement of standard cells and filler cells may enhance packing density and circuit performance.

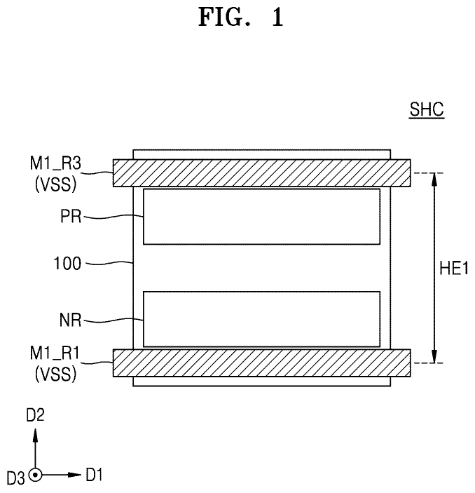

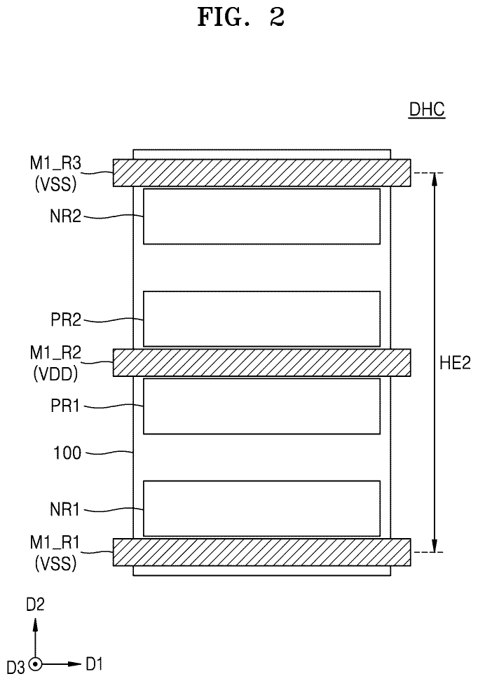

FIGS. 1 and 2 are conceptual diagrams for explaining logic cells of an example of an integrated circuit device.

Referring to FIG. 1, a single height cell SHC may be provided. In detail, a first power wiring M1_R1 and a second power wiring M1_R2 may be provided under a substrate 100. The first power wiring M1_R1 may be a path through which a source voltage VSS, for example, a ground voltage, is provided. The second power wiring M1_R2 may be a path through which a drain voltage VDD, for example, a power voltage, is provided.

The single height cell SHC may be defined between the first power wiring M1_R1 and the second power wiring M1_R2. The single height cell SHC may include one PMOSFET region PR and one NMOSFET region NR. In other words, the single height cell SHC may have a CMOS structure provided between the first power wiring M1_R1 and the second power wiring M1_R2.

The PMOSFET region PR and the NMOSFET region NR may have the same width in a second direction D2. The length of the single height cell SHC in the second direction D2 may be defined as a first height HE1. The first height HE1 may be substantially the same as a distance (for example, a pitch) between the first power wiring M1_R1 and the second power wiring M1_R2.

The single height cell SHC may form a single logic cell. Herein, a logic cell may refer to a logic element (for example, AND, OR, XOR, XNOR, an inverter, etc.) that performs a certain function. In other words, the logic cell may include transistors for forming a logic element and wiring connecting the transistors to each other.

Referring to FIG. 2, a double height cell DHC may be provided. In detail, the first power wiring M1_R1, the second power wiring M1_R2, and a third power wiring M1_R3 may be provided on the substrate 100. The second power wiring M1_R2 may be arranged between the first power wiring M1_R1 and the third power wiring M1_R3. The third power wiring M1_R3 may be a path through which the source voltage VSS is provided.

The double height cell DHC may be defined between the first power wiring M1_R1 and the third power wiring M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the first power wiring M1_R1. The second NMOSFET region NR2 may be adjacent to the third power wiring M1_R3. The first and second PMOSFET regions PR1 and PR2 may be adjacent to the second power wiring M1_R2. In a plan view, the second power wiring M1_R2 may be arranged between the first and second PMOSFET regions PR1 and PR2.

The length of the double height cell DHC in the second direction D2 may be defined as a second height HE2. The second height HE2 may be approximately twice the first height HE1 of FIG. 1. The first and second PMOSFET regions PR1 and PR2 of the double height cell DHC may be combined to operate as one PMOSFET region. Therefore, the size of a channel of a PMOS transistor of the double height cell DHC may be greater than the size of a channel of a PMOS transistor of the single height cell SHC of FIG. 1.

For example, the size of the channel of the PMOS transistor of the double height cell DHC may be approximately twice the size of the channel of the PMOS transistor of the single height cell SHC. As a result, the double height cell DHC may operate at a higher speed compared to the single height cell SHC. In the present disclosure, the double height cell DHC shown in FIG. 2 may be defined as a multi-height cell. Although not shown, the multi-height cell may include a triple height cell having a cell height approximately three times that of the single height cell SHC.

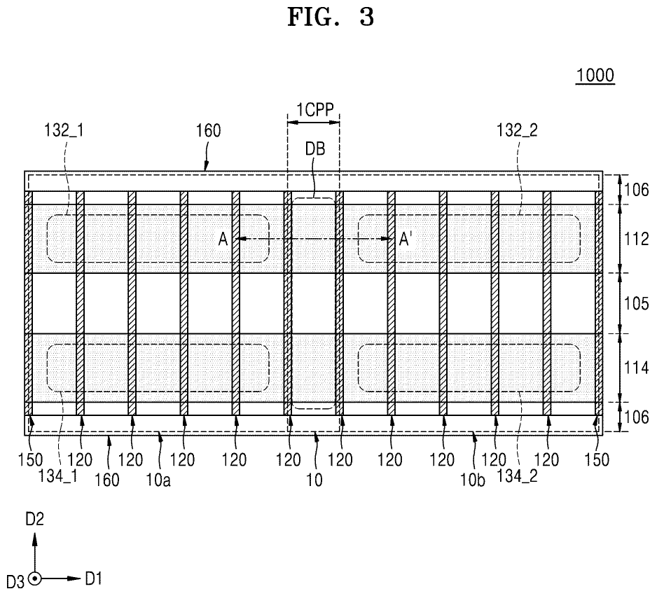

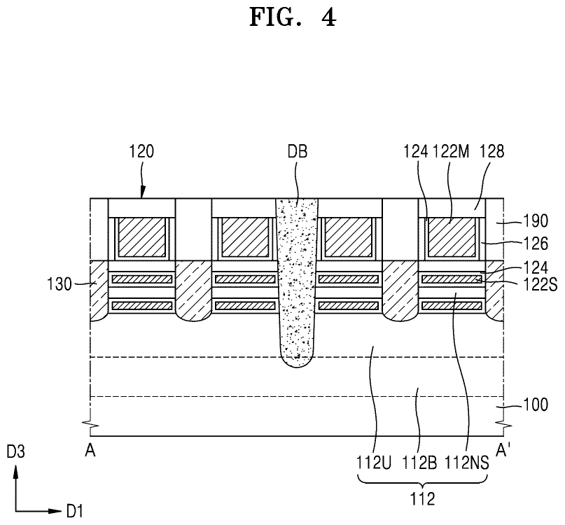

FIG. 3 is an integrated circuit layout diagram 1000 for explaining an example of an integrated circuit. FIG. 4 is an example cross-sectional view taken along a line A-A′ of FIG. 3.

Referring to FIGS. 3 and 4, a first cell 10a, a second cell 10b, and a first filler cell 10 may be formed on the substrate 100.

The substrate 100 may be a silicon substrate or a silicon-on-insulator (SOI). In contrast, the substrate 100 may include, but is not limited thereto, silicon germanium, silicon germanium on insulator (SGOI), indium antimonide, a lead telluride compound, indium arsenide, indium phosphide, gallium arsenide, or gallium antimonide.

A first active region 112 may be defined in a first direction D1. The first active region 112 may be where a p-type transistor is formed. The first active region 112 may include, for example, a well region doped with n-type impurities. Hereinafter, the first active region 112 may correspond to the PMOSFET region PR of FIG. 1, the first PMOSFET region PR1 of FIG. 2, or the second PMOSFET region PR2 of FIG. 2.

The first active region 112 may include a first lower active region 112B, a first upper active region 112U, and a first nanosheet 112NS. The first lower active region 112B may have a side wall defined by a deep trench. The first upper active region 112U may have a pin shape protruding from the first lower active region 112B. The first upper active region 112U may have a side wall defined by a shallow trench rather than a deep trench. The first nanosheet 112NS may be spaced apart from the first upper active region 112U. FIG. 3 shows that two nanosheets 112NS are included, but this is only an example for convenience of explanation, and the present disclosure is not limited thereto.

A second active region 114 may be defined in the first direction D1. The second active region 114 may be spaced apart from the first active region 112 in the second direction D2. The first active region 112 and the second active region 114 may be separated from each other by a deep trench. The second active region 114 may be where an n-type transistor is formed. The second active region may include, for example, a well region doped with p-type impurities. Hereinafter, the second active region 114 may correspond to the NMOSFET region NR of FIG. 1, the first NMOSFET region NR1 of FIG. 2, or the second NMOSFET region NR2 of FIG. 2.

Although not shown in FIGS. 3 and 4, the second active region 114 may also include a second lower active region, a second upper active region, and a second nanosheet, similar to the structure of the first active region 112.

Referring to FIG. 3 again, each of the first cell 10a, the second cell 10b, and the first filler cell 10 may include the first active region 112 and the second active region 114.

An active region separation film 105 may be formed on the substrate 100. The active region separation film 105 may cross between the first active region 112 and the second active region 114. The active region separation film 105 may extend in the first direction D1. The active region separation film 105 may occupy a deep trench that separates the first active region 112 and the second active region 114 from each other.

A cell separation film 106 may be formed on the substrate 100. The cell separation film 106 may occupy a deep trench that separates the first active region 112 and the second active region 114 from each other. The cell separation film 106 may extend in the first direction D1 along a boundary of the first cell 10a, a boundary of the second cell 10b, and a boundary of the first filler cell 10. Each of the active region separation film 105 and the cell separation film 106 may include an insulating material.

Each of the active region separation film 105 and the cell separation film 106 may include an insulating material that occupies the deep trench defining the first active region 112 and the second active region 114. In the following description, the active region separation film 105 may be an insulating material film arranged between the first active region 112 and the second active region 114, which are included in one cell. In other words, the active region separation film 105 may be an insulating material film arranged within the cell. The cell separation film 106 may not be arranged within a cell and may be an insulating material film extending along a cell boundary extending in the first direction D1 among cell boundaries. In other words, the cell separation film 106 may be an insulating material film arranged along the cell boundary.

An integrated circuit device according to implementations may include a plurality of gate stacks 120 and a plurality of insulating gates 150. A gate stack 120 and an insulating gate 150 may each extend in the second direction D2. The plurality of gate stacks 120 may be adjacent to each other in the first direction D1.

The plurality of gate stacks 120 adjacent to each other in the first direction D1 may be spaced apart from each other by contacted poly pitch (1CPP). For the purposes of this disclosure, 1CPP includes the minimum distance between the center of two polysilicon gates. Likewise, the gate stack 120 and the insulating gate 150, which are adjacent to each other, may be spaced apart from each other by 1CPP.

In other words, when there are a first gate stack and a second gate stack that are adjacent to each other, if a distance between a center line of the first gate stack extending in the second direction D2 and a center line of the second gate stack extending in the second direction D2 is 1CPP, this may mean that no other gate stack or insulating gate is arranged between the first gate stack and the second gate stack.

Each of the gate stack 120 and the insulating gate 150 may be arranged over the first active region 112 and the second active region 114. Each of the gate stack 120 and the insulating gate 150 may extend from the first active region 112 to the second active region 114. The gate stack 120 and the insulating gate 150 may cross the active region separation film 105. A portion of the gate stack 120 and a portion of the insulating gate 150 may each extend over the cell separation film 106.

Referring to FIG. 4, the gate stack 120 may include a main gate 122M, a sub-gate 122S, a gate insulating film 124, a gate spacer 126, and a gate capping film 128. In some cases, the gate stack 120 may not include the gate capping film 128. The gate spacer 126 may define a gate trench in which the gate insulating film 124 and the main gate 122M may be formed. The gate spacer 126 may include, for example, an insulating material. The gate insulating film 124 may be formed along a perimeter of the first nanosheet 112NS. Although not shown, the gate insulating film 124 may be formed along a perimeter of the second nanosheet. The gate insulating film 124 may include, for example, at least one of silicon oxide or a high-k material. The high-k material may be, for example, a material with a dielectric constant greater than that of silicon oxide. The main gate 122M and the sub-gate 122S may be formed on the gate insulating film 124. The sub-gate 122S may surround the first nanosheet 112NS. Although not shown, the sub-gate 122S may surround the second nanosheet. Each of the main gate 122M and the sub-gate 122S may include, for example, at least one of a metal (including a metal alloy including two or more metals), metal nitride, metal carbide, metal silicide, or a semiconductor material. The gate capping film 128 may be arranged on the main gate 122M. The gate capping film 128 may include, for example, an insulating material.

The insulating gate 150 may at least partially split the first active region 112 and the second active region 114. In some implementations, a portion of a side wall of the insulating gate 150 may be in contact with a semiconductor material film included in each of the first active region 112 and the second active region 114.

The insulating gate 150 may cross the active region separation film 105. The insulating gate 150 may be arranged on the active region separation film 105, and in some implementations, a portion of the insulating gate 150 may be recessed into the active region separation film 105. The insulating gate 150 may include, for example, an insulating material. The insulating gate 150 may be a single film, and in some implementations, the insulating gate 150 may have a multilayer structure including two or more films.

A semiconductor pattern 130 may be formed between adjacent gate stacks 120. The semiconductor pattern 130 may be formed by removing portions of the first and second active regions 112 and 114 to form a recess and then filling the recess through an epitaxial process. At least a portion of the semiconductor pattern 130 may be included in a source/drain region of a transistor. The semiconductor pattern 130 formed on the first active region 112 may be doped with impurities of a different conductivity type than the semiconductor pattern 130 formed on the second active region 114.

A cell gate cut pattern 160 may be arranged on the cell separation film 106. The cell gate cut pattern 160 may extend in the first direction D1. The cell gate cut pattern 160 may extend in the first direction D1 along a boundary of the first cell 10a, a boundary of the first filler cell 10, and a boundary of the second cell 10b. The gate stack 120 and the insulating gate 150 may be arranged between cell gate cut patterns 160 spaced apart from each other in the first direction D1. The cell gate cut pattern 160 may include, for example, an insulating material.

The cell gate cut pattern 160 may be cut through a region within the gate stack 120 at a cell boundary. The cell gate cut pattern 160 may be in contact with the gate stack 120 and the insulating gate 150. The cell gate cut pattern 160 may be in contact with an end portion of the gate stack 120 and an end portion of the insulating gate 150, each extending in the first direction D1. The first cell 10a, the first filler cell 10, and the second cell 10b may further include the cell gate cut pattern 160 formed along their respective boundaries extending in the first direction D1.

The first filler cell 10 may be arranged between the first cell 10a and the second cell 10b. The first cell 10a and the second cell 10b may be adjacent to each other in the first direction D1 with the first filler cell 10 therebetween. A boundary between the first filler cell 10 and the first cell 10a extends in the second direction D2, and a boundary between the first filler cell 10 and the second cell 10b extends in the second direction D2.

The first filler cell 10 may cross the first active region 112 and the second active region 114 and may include two gate stacks 120 adjacent to each other in the first direction D1. Each of the gate stacks 120 may be arranged at a boundary of the first filler cell 10, which extends in the second direction D2. A separation structure DB may be arranged between the two gate stacks 120 adjacent to each other in the first direction D1.

The separation structure DB may at least partially split the first active region 112 and the second active region 114. Referring to FIG. 4, the separation structure DB may split the first upper active region 112U of the first active region 112. Although it is shown that the separation structure DB split a portion of the first lower active region 112B of the first active region 112, this is only an example, and the present disclosure is not limited thereto.

The first filler cell 10 may have a one-pitch dimension in the first direction D1. The one-pitch dimension may be 1CPP. In other words, when the first filler cell 10 has a first filler cell boundary and a second filler cell boundary, each extending in the second direction D2, the first filler cell 10 may extend across the one-pitch dimension from the first filler cell boundary to the second filler cell boundary.

The first cell 10a may form a boundary with the first filler cell 10. The first filler cell 10 may form a boundary with the first cell 10a in one of the gate stacks 120 included in the first filler cell 10. The first cell 10a and the first filler cell 10, which are adjacent to each other, may share the gate stack 120 at a common boundary. Although FIG. 3 shows that the first cell 10a has a width of 5CPP, this is only an example, and the present disclosure is not limited thereto.

The second cell 10b may form a boundary with the first filler cell 10. The first filler cell 10 may form a boundary with the second cell 10b in one of the gate stacks 120 included in the first filler cell 10. The second cell 10b and the first filler cell 10, which are adjacent to each other, may share the gate stack 120 at a common boundary. Although FIG. 3 shows that the second cell 10b has a width of 5CPP, this is only an example, and the present disclosure is not limited thereto.

The first cell 10a may further include the first active region 112 and the second active region 114. The gate stack 120 included in the first cell 10a may intersect with the first active region 112 and the second active region 114. The first cell 10a may include a first p-type transistor 132_1 and a first n-type transistor 134_1 that are each integrated. The first p-type transistor 132_1 may be formed at a position where the gate stack 120 and the first active region 112 intersect with each other, and the first n-type transistor 134_1 may be formed at a position where the gate stack 120 and the second active region 114 intersect with each other. For example, the first p-type transistor 132_1 may include the main gate 122M, the sub-gate 122S, the first nanosheet 112NS as a channel region, and the semiconductor pattern 130 as a source/drain region.

The second cell 10b may further include the first active region 112 and the second active region 114. The gate stack 120 included in the second cell 10b may intersect with the first active region 112 and the second active region 114. The second cell 10b may include a second p-type transistor 132_2 and a second n-type transistor 134_2 that are each integrated. The second p-type transistor 132_2 may be formed at a position where the gate stack 120 and the first active region 112 intersect with each other, and the second n-type transistor 134_2 may be formed at a position where the gate stack 120 and the second active region 114 intersect with each other. For example, the second p-type transistor 132_2 may include the main gate 122M, the sub-gate 122S, the first nanosheet 112NS as a channel region, and the semiconductor pattern 130 as a source/drain region.

The first p-type transistor 132_1 and the second p-type transistor 132_2 are formed on the first active region 112, and the first n-type transistor 134_1 and the second n-type transistor 134_2 are formed on the second active region 114.

The first filler cell 10 arranged between the first cell 10a and the second cell 10b includes two gate stacks 120 and the separation structure DB arranged between the two neighboring gate stacks 120. Because the separation structure DB at least partially splits the first active region 112 and the second active region 114, each of the first active region 112 and the second active region 114 may be divided into at least three parts in the first direction D1. In the first filler cell 10, the separation structure DB may be arranged to extend in the second direction D2 across the first and second active regions 112 and 114 between the gate stacks 120.

In some implementations, the separation structure DB may include a nitride-based material, but the present disclosure is not limited thereto. In addition, in some implementations, the separation structure DB may not include an oxide.

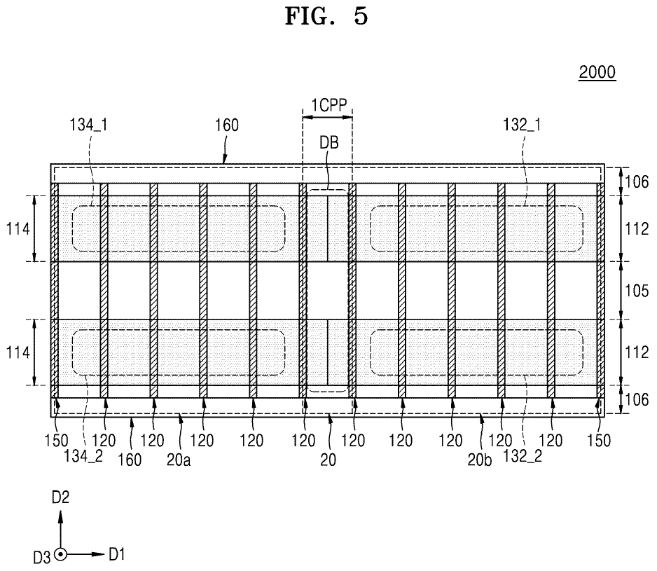

FIG. 5 is an integrated circuit layout diagram 2000 for explaining an example of an integrated circuit. The integrated circuit layout diagram 2000 described with reference to FIG. 5 is not mutually exclusive from the integrated circuit layout diagram 1000 described with reference to FIGS. 3 and 4, and it will be understood that elements having the same reference numeral refer to the same element. Hereinafter, redundant descriptions of the same components may be simplified or omitted, and differences from the integrated circuit layout diagram 1000 of FIGS. 3 and 4 may be mainly explained.

Referring to FIG. 5, a second filler cell 20 may be arranged between a first cell 20a and a second cell 20b.

The first cell 20a may include the second active region 114, the second cell 20b may include the first active region 112, and the second filler cell 20 may include the first active region 112 and the second active region 114.

Each of the gate stack 120 and the insulating gate 150 may be arranged over the first active region 112 and the second active region 114. The gate stack 120 and the insulating gate 150 may extend in the second direction D2 across the active region separation film 105 in the first active region 112 and the second active region 114. A portion of the gate stack 120 and a portion of the insulating gate 150 may each extend over the cell separation film 106.

The first cell 20a and the second cell 20b may be adjacent to each other in the first direction D1 with the second filler cell 20 therebetween. A boundary between the second filler cell 20 and the first cell 20a extends in the second direction D2, and a boundary between the second filler cell 20 and the second cell 20b extends in the second direction D2.

The second filler cell 20 may include both the first active region 112 and the second active region 114 and may include a boundary area between the first active region 112 and the second active region 114. Although t is shown that a boundary between the first active region 112 and the second active region 114 is arranged at a center of the second filler cell 20, this is only an example, and the present disclosure is not limited thereto.

The second filler cell 20 may include two gate stacks 120 adjacent to each other in the first direction D1. Each of the gate stacks 120 may be arranged at a boundary of the second filler cell 20, which extends in the second direction D2. The separation structure DB may be arranged between the two gate stacks 120 adjacent to each other in the first direction D1. The separation structure DB may separate the first and second active regions 112 and 114 from each other at the boundary between the first active region 112 and the second active region 114.

The first cell 20a may include two second active regions 114. The gate stack 120 included in the first cell 20a may intersect with the two second active regions 114. The first cell 20a may include the first n-type transistor 134_1 and the second n-type transistor 134_2 that are each integrated. Each of the first and second n-type transistors 134_1 and 134_2 may be formed at a position where the gate stack 120 and the second active region 114 intersect with each other. For example, each of the first and second n-type transistors 134_1 and 134_2 may include the main gate 122M, the sub-gate 122S, the first nanosheet 112NS as a channel region, and the semiconductor pattern 130 as a source/drain region.

The second cell 20b may include two first active regions 112. The gate stack 120 included in the second cell 20b may intersect with the two first active regions 112. The second cell 20b may include the first p-type transistor 132_1 and the second p-type transistor 132_2 that are each integrated. Each of the first and second p-type transistors 132_1 and 132_2 may be formed at a position where the gate stack 120 and the first active region 112 intersect with each other. For example, each of the first and second p-type transistors 132_1 and 132_2 may include the main gate 122M, the sub-gate 122S, the first nanosheet 112NS as a channel region, and the semiconductor pattern 130 as a source/drain region.

The first p-type transistor 132_1 and the second p-type transistor 132_2 are formed on the first active region 112, and the first n-type transistor 134_1 and the second n-type transistor 134_2 are formed on the second active region 114.

The second filler cell 20 arranged between the first cell 20a and the second cell 20b may include two gate stacks 120 and the separation structure DB arranged between the two neighboring gate stacks 120. The separation structure DB may separate from each other the first active region 112 and the second active region 114 that are adjacent to each other in the first direction D1. In other words, the separation structure DB may be formed at a boundary of an active region including transistors of different conductivity types.

In the second filler cell 20, the separation structure DB may be arranged to extend in the second direction D2 across the first and second active regions 112 and 114 between the two gate stacks 120. The gate stack 120 arranged at the boundary between the first cell 20a and the second filler cell 20 extends from the second active region 114 in the second direction D2, and the gate stack 120 arranged at the boundary between the second cell 20b and the second filler cell 20 extends from the first active region 112 in the second direction D2.

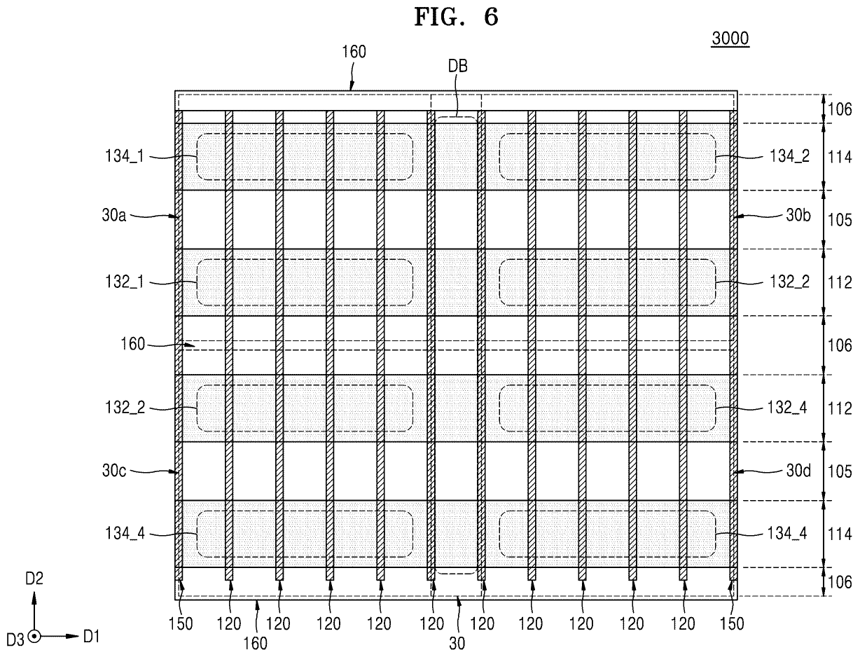

FIG. 6 is an integrated circuit layout diagram 3000 for explaining an example of an integrated circuit. The integrated circuit layout diagram 3000 described with reference to FIG. 6 is not mutually exclusive from the integrated circuit layout diagram 1000 described with reference to FIGS. 3 and 4, and it will be understood that elements having the same reference numeral refer to the same element. Hereinafter, redundant descriptions of the same components may be simplified or omitted, and differences from the integrated circuit layout diagram 1000 of FIGS. 3 and 4 may be mainly explained.

Referring to FIG. 6, the integrated circuit may include a first cell 30a, a second cell 30b, a third cell 30c, a fourth cell 30d, and a third filler cell 30.

Each of the first cell 30a, the second cell 30b, the third cell 30c, and the fourth cell 30d may have a width of 5CPP in the first direction D1, and the third filler cell 30 may have a width of 1CPP in the first direction D1. When each of the first cell 30a, the second cell 30b, the third cell 30c, and the fourth cell 30d has a height of H in the second direction D2, the third filler cell 30 may have a height of 2H.

The third filler cell 30 may be arranged between the first cell 30a and the second cell 30b and between the third cell 30c and the fourth cell 30d, and the third filler cell 30 may include the separation structure DB extending between two gate stacks 120 in the second direction D2.

The first cell 30a and the third cell 30c may be adjacent to each other in the second direction D2, the second cell 30b and the fourth cell 30d may be adjacent to each other in the second direction D2, and the third filler cell 30 may be adjacent to the first cell 30a, the second cell 30b, the third cell 30c, and the fourth cell 30d in the first direction D1.

The cell gate cut pattern 160 may be arranged between the first cell 30a and the third cell 30c and between the second cell 30b and the fourth cell 30d, and may be additionally arranged at a boundary connecting the first cell 30a, the third filler cell 30, and the second cell 30b to each other and at a boundary connecting the third cell 30c, the third filler cell 30, and the fourth cell 30d to each other. The cell gate cut pattern 160 arranged between the first cell 30a and the third cell 30c and between the second cell 30b and the fourth cell 30d may not extend into the third filler cell 30.

Each of the first to fourth cells 30a, 30b, 30c, and 30d includes a p-type transistor and an n-type transistor that are formed on the first active region 112 and the second active region 114. In detail, the first cell 30a may include the first p-type transistor 132_1 on the first active region 112 and the first n-type transistor 134_1 on the second active region 114, the second cell 30b may include the second p-type transistor 132_2 on the first active region 112 and the second n-type transistor 134_2 on the second active region 114, the third cell 30c may include a third p-type transistor 132_3 on the first active region 112 and a third n-type transistor 134_3 on the second active region 114, and the fourth cell 30d may include a fourth p-type transistor 132_4 on the first active region 112 and a fourth n-type transistor 134_4 on the second active region 114.

The separation structure DB included in the third filler cell 30 may have a greater height than the height of each of the first to fourth cells 30a, 30b, 30c, and 30d in the second direction D2 and may extend in the second direction D2. The separation structure DB may extend across two first active regions 112 and two second active regions 114 and may at least partially split each of the active regions. The third filler cell 30 is adjacent to a total of four cells, and unlike in the integrated circuit layout diagrams 1000 and 2000 of FIGS. 3 and 5, three or more cells may be split by one separation structure DB.

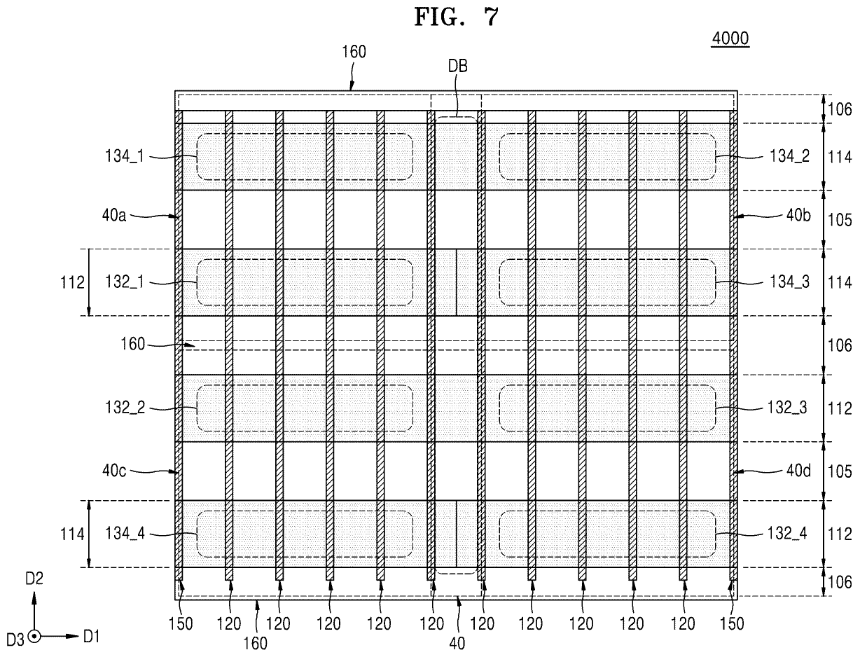

FIG. 7 is an integrated circuit layout diagram 4000 for explaining an example of an integrated circuit. The integrated circuit layout diagram 4000 described with reference to FIG. 7 is not mutually exclusive from the integrated circuit layout diagram 1000 described with reference to FIGS. 3 and 4, and it will be understood that elements having the same reference numeral refer to the same element. Hereinafter, redundant descriptions of the same components may be simplified or omitted, and differences from the integrated circuit layout diagram 1000 of FIGS. 3 and 4 may be mainly explained.

Referring to FIG. 7, the integrated circuit may include a first cell 40a, a second cell 40b, a third cell 40c, a fourth cell 40d, and a fourth filler cell 40.

The arrangement relationship of the first cell 40a, the second cell 40b, the third cell 40c, the fourth cell 40d, the fourth filler cell 40, and the cell gate cut pattern 160 is similar to the arrangement relationship of the first cell 30a, the second cell 30b, the third cell 30c, the fourth cell 30d, the third filler cell 30, and the cell gate cut pattern 160 of FIG. 6, and accordingly, descriptions thereof may be omitted.

Each of the first cell 40a and the third cell 40c includes a p-type transistor formed on the first active region 112 and an n-type transistor formed on the second active region 114, the second cell 40b includes an n-type transistor formed on the second active region 114, and the fourth cell 40d includes a p-type transistor formed on the first active region 112. In detail, the first cell 40a may include the first p-type transistor 132_1 on the first active region 112 and the first n-type transistor 134_1 on the second active region 114, and the third cell 40c may include the second p-type transistor 132_2 on the first active region 112 and the fourth n-type transistor 134_4 on the second active region 114. The second cell 40b may include the second and third n-type transistors 134_2 and 134_3 on the second active region 114, and the fourth cell 40d may include the third and fourth p-type transistors 132_3 and 132_4 on the first active region 112.

The separation structure DB included in the fourth filler cell 40 may have a greater height than the height of each of the first to fourth cells 40a, 40b, 40c, and 40d in the second direction D2 and may extend in the second direction D2. The separation structure DB may extend across both boundaries of the first active region 112 and the second active region 114. In contrast to the third filler cell 30 being across the first active region 112 and the second active region 114 that are spaced apart from each other (see FIG. 6), the fourth filler cell 40 may separate from each other the first active region 112 and the second active region 114 that are adjacent to each other in the first direction D1. In other words, the separation structure DB may be formed at a boundary of an active region including transistors of different conductivity types. Although not shown in the drawing of the present specification, a well-tap cell may be arranged in the second cell 40b and/or the fourth cell 40d in the integrated circuit layout diagram 4000 of FIG. 7. In some implementations, the well-tap cell may mitigate latch-up issues in a MOSFET caused by coupling effects. The filler cell according to the present disclosure may also be applied while maintaining a width of 1CPP even when one or more well-tap cells are included in an integrated circuit layout diagram, thereby improving the degree of integration of the integrated circuit shown in the layout diagram.

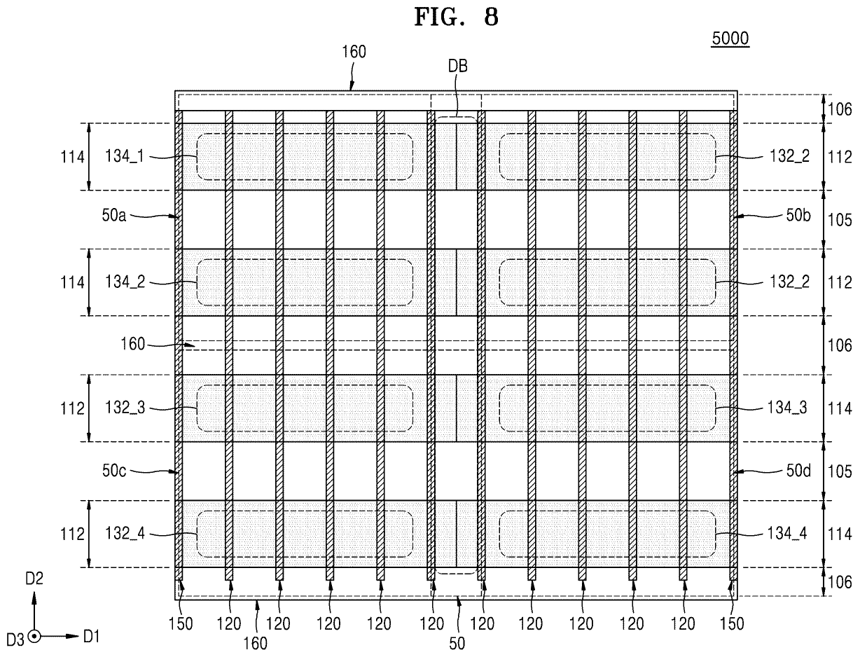

FIG. 8 is an integrated circuit layout diagram 5000 for explaining an example of an integrated circuit. The integrated circuit layout diagram 5000 described with reference to FIG. 8 is not mutually exclusive from the integrated circuit layout diagram 1000 described with reference to FIGS. 3 and 4, and it will be understood that elements having the same reference numeral refer to the same element. Hereinafter, redundant descriptions of the same components may be simplified or omitted, and differences from the integrated circuit layout diagram 1000 of FIGS. 3 and 4 may be mainly explained.

Referring to FIG. 8, the integrated circuit may include a first cell 50a, a second cell 50b, a third cell 50c, a fourth cell 50d, and a fifth filler cell 50.

The arrangement relationship of the first cell 50a, the second cell 50b, the third cell 50c, the fourth cell 50d, the fifth filler cell 50, and the cell gate cut pattern 160 is similar to the arrangement relationship of the first cell 30a, the second cell 30b, the third cell 30c, the fourth cell 30d, the third filler cell 30, and the cell gate cut pattern 160 of FIG. 6, and accordingly, descriptions thereof may be omitted.

Each of the first cell 50a and the fourth cell 50d includes an n-type transistor formed on the second active region 114, and each of the second cell 50b and the third cell 50c includes a p-type transistor formed on the first active region 112. In detail, the first cell 50a may include the first and second n-type transistors 134_1 and 134_2 on the second active region 114, and the fourth cell 50d may include the third and fourth n-type transistors 134_3 and 134_4 on the second active region 114. The second cell 50b may include the first and second p-type transistors 132_1 and 132_2 on the first active region 112, and the third cell 50c may include the third and fourth p-type transistors 132_3 and 132_4 on the first active region 112.

The separation structure DB included in the fifth filler cell 50 may have a greater height than the height of each of the first to fourth cells 50a, 50b, 50c, and 50d in the second direction D2 and may extend in the second direction D2. The separation structure DB may extend across both boundaries of the first active region 112 and the second active region 114. In contrast to the third filler cell 30 being across the first active region 112 and the second active region 114 that are spaced apart from each other (see FIG. 6), the fifth filler cell 50 may separate from each other the first active region 112 and the second active region 114 that are adjacent to each other in the first direction D1. In other words, the separation structure DB may be formed at a boundary of an active region including transistors of different conductivity types.

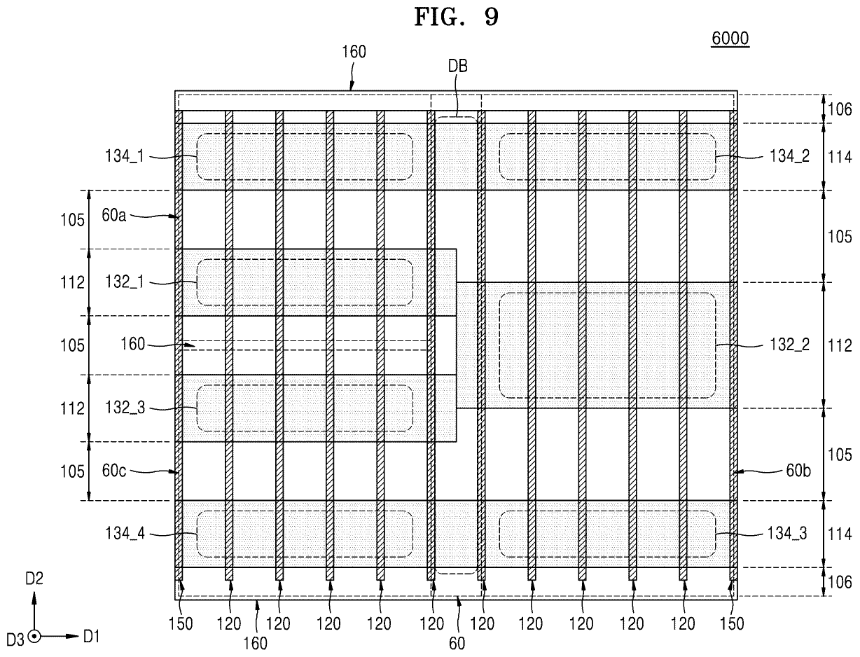

FIG. 9 is an integrated circuit layout diagram 6000 for explaining an example of an integrated circuit. The integrated circuit layout diagram 6000 described with reference to FIG. 9 is not mutually exclusive from the integrated circuit layout diagram 1000 described with reference to FIGS. 3 and 4, and it will be understood that elements having the same reference numeral refer to the same element. Hereinafter, redundant descriptions of the same components may be simplified or omitted, and differences from the integrated circuit layout diagram 1000 of FIGS. 3 and 4 may be mainly explained.

Referring to FIG. 9, the integrated circuit may include a first cell 60a, a second cell 60b, a third cell 60c, and a sixth filler cell 60.

Each of the first cell 60a, the second cell 60b, and the third cell 60c may have a width of 5CPP in the first direction D1, and the sixth filler cell 60 may have a width of 1CPP in the first direction D1. When each of the first cell 60a and the third cell 60c has a height of H in the second direction D2, each of the second cell 60 b and the sixth filler cell 60 may have a height of 2H.

The second cell 60b may not only have a greater cell height than the first cell 60a and the third cell 60c, but may also be formed by connecting the same active regions to each other in the second direction D2. In detail, instead of including two first active regions 112 and two second active regions 114, as the double height cell DHC (see FIG. 2) including the first PMOSFET region PR1, the second PMOSFET region PR2, the first NMOSFET region NR1, and the second NMOSFET region NR2, the second cell 60b may include two second active regions 114 and one first active region 112 having a width in the second direction D2 twice that of the second active region 114.

The sixth filler cell 60 may be arranged between the first cell 60a and the second cell 60b and between the third cell 60c and the second cell 60b, and the sixth filler cell 60 may include the separation structure DB extending between two gate stacks 120 in the second direction D2.

The first cell 60a and the third cell 60c may be adjacent to each other in the second direction D2, and the sixth filler cell 60 may be adjacent to each of the first cell 60a, the second cell 60b, and the third cell 60c in the first direction D1.

The cell gate cut pattern 160 may be arranged between the first cell 60a and the third cell 60c, and may be additionally arranged at a boundary connecting the first cell 60a, the sixth filler cell 60, and the second cell 60b to each other and at a boundary connecting the third cell 60c, the sixth filler cell 60, and the second cell 60b to each other. The cell gate cut pattern 160 arranged between the first cell 60a and the third cell 60c may not extend into the sixth filler cell 60.

Each of the first to third cells 60a, 60b, and 60c may include a p-type transistor and an n-type transistor that are formed on the first active region 112 and the second active region 114. In detail, the first cell 60a may include the first p-type transistor 132_1 on the first active region 112 and the first n-type transistor 134_1 on the second active region 114, the second cell 60b may include the second and third n-type transistors 134_2 and 134_3 on the second active region 114 and the second p-type transistor 132_2 on the first active region 112 having a relatively large width, and the third cell 50c may include the third p-type transistor 132_3 on the first active region 112 and the fourth n-type transistor 134_4 on the second active region 114.

The separation structure DB included in the sixth filler cell 60 may have a greater height than the height of each of the first and third cells 60a and 60c in the second direction D2 and may extend in the second direction D2. The separation structure DB may extend across a plurality of first and second active regions 112 and 114 and may at least partially split each of the active regions. In particular, the sixth filler cell 60 may be arranged while maintaining a width of 1CPP even between cells having different active region widths.

In the case of the cells having different active region widths, the second cell 60b may include at least one portion where the width of an active region changes at a boundary with a neighboring cell (for example, the first cell 60a and the third cell 60c in the case of FIG. 9), and has two 90-degree bends (or jogs) at each portion where an active region width changes. In this case, a dummy cell having a larger area may be required than when cells having the same active region width are adjacent to each other side by side in the first and second directions D1 and D2. However, as shown in the integrated circuit layout diagram 6000 of FIG. 9, even when the cells having different active region widths are adjacent to each other, adjacent active regions may be separated from each other using only a single dummy cell having a width of 1CPP, thereby contributing to improvement of the degree of integration of the integrated circuit.

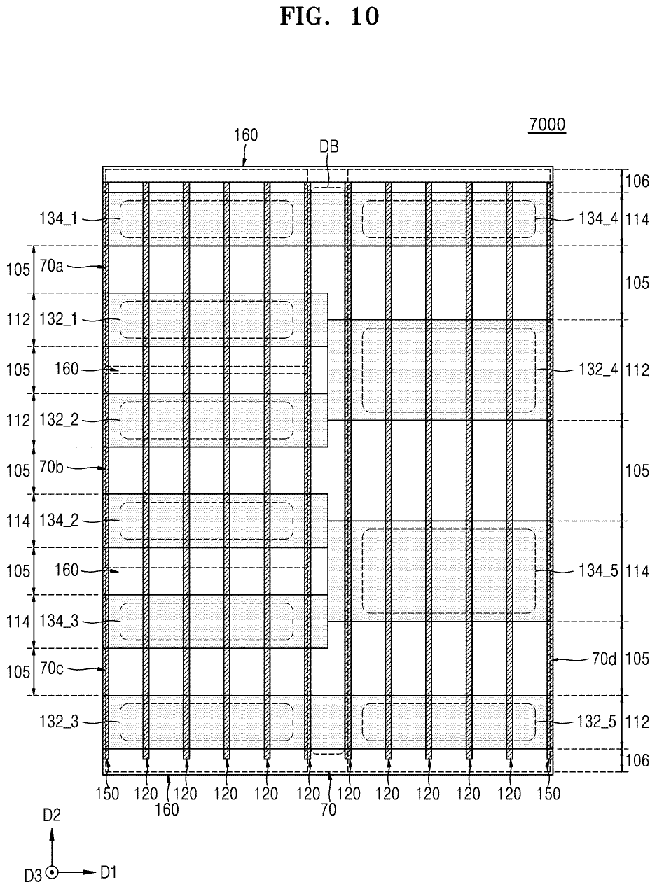

FIG. 10 is an integrated circuit layout diagram 7000 for explaining an example of an integrated circuit. The integrated circuit layout diagram 7000 described with reference to FIG. 10 is not mutually exclusive from the integrated circuit layout diagram 1000 described with reference to FIGS. 3 and 4, and it will be understood that elements having the same reference numeral refer to the same element. Hereinafter, redundant descriptions of the same components may be simplified or omitted, and differences from the integrated circuit layout diagram 1000 of FIGS. 3 and 4 may be mainly explained.

Referring to FIG. 10, the integrated circuit may include a first cell 70a, a second cell 70b, a third cell 70c, a fourth cell 70d, and a seventh filler cell 70.

Each of the first cell 70a, the second cell 70b, the third cell 70c, and the fourth cell 70d may have a width of 5CPP in the first direction D1, and the seventh filler cell 70 may have a width of 1CPP in the first direction D1. When each of the first cell 70 a, the second cell 70 b, and the third cell 70c has a height of H in the second direction D2, each of the fourth cell 70d and the seventh filler cell 70 may have a height of 3H.

The seventh filler cell 70 may be arranged between the first cell 70a and the fourth cell 70d, between the second cell 70b and the fourth cell 70d, and between the third cell 70c and the fourth cell 70d, and the seventh filler cell 70 may include the separation structure DB extending between two gate stacks 120 in the second direction D2.

The first cell 70a and the second cell 70b may be adjacent to each other in the second direction D2, the second cell 70b and the third cell 70c may be adjacent to each other in the second direction D2, and the seventh filler cell 70 may be adjacent to the first cell 70a, the second cell 70b, the third cell 70c, and the fourth cell 70d in the first direction D1.

The cell gate cut pattern 160 may be arranged between the first cell 70a and the second cell 70b and between the second cell 70b and the third cell 70c, and may be additionally arranged at a boundary connecting the first cell 70a, the seventh filler cell 70, and the fourth cell 70d to each other and at a boundary connecting the third cell 70c, the seventh filler cell 70, and the fourth cell 70d to each other. The cell gate cut pattern 160 arranged between the first cell 70a and the second cell 70b and between the second cell 70b and the third cell 70c may not extend into the seventh filler cell 70.

The fourth cell 70d may not only have a greater cell height than the first to third cells 70a, 70b, and 70c, but may also be formed by connecting two of the same active regions to each other in the second direction D2. In detail, instead of including three first active regions 112 and three second active regions 114, the fourth cell 70d may include two first active regions 112 and two second active regions 114, wherein one of the two first active regions 112 may have a width in the second direction D2 twice that of the other one of the two first active regions 112, and one of the two second active regions 114 may have a width in the second direction D2 twice that of the other one of the two second active regions 114.

Each of the first to fourth cells 70a, 70b, 70c, and 70d may include a p-type transistor and an n-type transistor that are formed on the first active region 112 and the second active region 114. In detail, the first cell 70a may include the first p-type transistor 132_1 on the first active region 112 and the first n-type transistor 134_1 on the second active region 114, the second cell 70b may include the second p-type transistor 132_2 on the first active region 112 and the second n-type transistor 134_2 on the second active region 114, and the third cell 70c may include the third p-type transistor 132_3 on the first active region 112 and the third n-type transistor 134_3 on the second active region 114. The fourth cell 70d may include the fourth p-type transistor 132_4 on the first active region 112 having a relatively large width, a fifth p-type transistor 132_5 on the first active region 112 having the same width as that of the first active region 112 in each of the first to third cells 70a, 70b, and 70c, the fourth n-type transistor 134_4 on the second active region 114, and a fifth n-type transistor 134_5 on the second active region 114 having a relatively large width.

The separation structure DB included in the seventh filler cell 70 may have a greater height than the height of each of the first to third cells 70a, 70b, and 70c in the second direction D2 and may extend in the second direction D2. The separation structure DB may extend across a plurality of first and second active regions 112 and 114 and may at least partially split each of the active regions. In particular, the seventh filler cell 70 may be arranged while maintaining a width of 1CPP even when a plurality of sections having different active regions widths are included.

Similar to the second cell 60b of FIG. 9, the fourth cell 70d of FIG. 10 may have a 90-degree bend at a portion where an active region width changes at a boundary with a neighboring cell (for example, the first to third cells 70a, 70b, and 70c in the case of FIG. 10). In this case, a dummy cell having a larger area may be required than when cells having the same active region width are adjacent to each other side by side in the first and second directions D1 and D2 as described above, but referring to the integrated circuit layout diagram 7000 of FIG. 10, even when a cell including two different active region widths is included, adjacent active regions may be separated from each other using only a single dummy cell having a width of 1CPP, thereby contributing to improvement of the degree of integration of the integrated circuit.

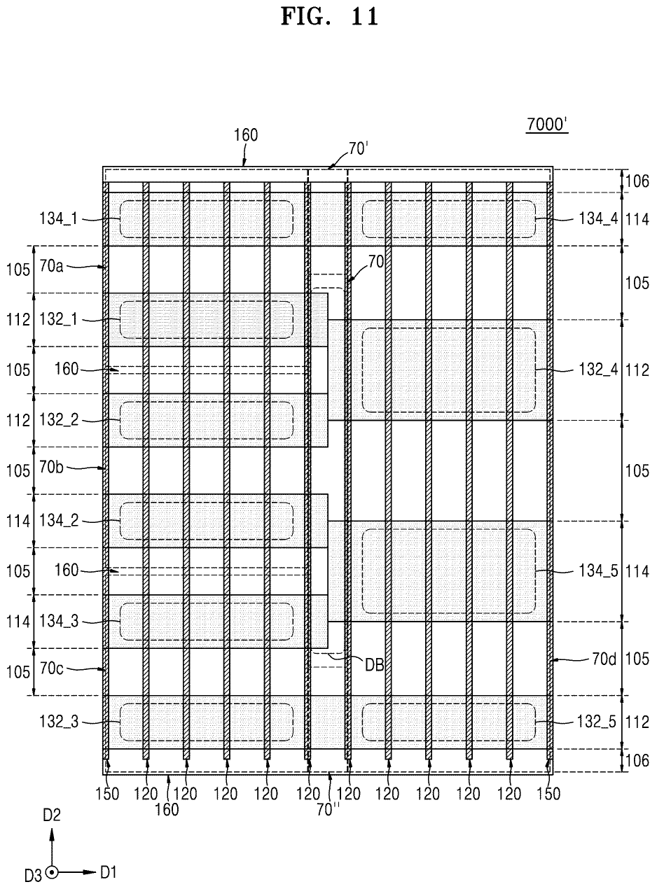

FIG. 11 is an integrated circuit layout diagram 7000′ for explaining an example of an integrated circuit. The integrated circuit layout diagram 7000′ described with reference to FIG. 11 may be the same as the integrated circuit layout diagram 7000 described with reference to FIG. 10, except that the height of the seventh filler cell 70 in the second direction D2 is different from that in FIG. 10. Therefore, hereinafter, descriptions of the first to fourth cells 70a, 70b, 70c, and 70d are omitted, and the seventh filler cell 70 may be mainly described.

Referring to FIG. 11, both end portions of the seventh filler cell 70 may not extend to both ends of the layout diagram in the second direction D2 as in FIG. 10. The first active region 112 of FIG. 11, which is arranged at a lowermost end, may extend in the first direction D1 without a change in conductivity type across the third cell 70c and the fourth cell 70d. Likewise, the second active region 114 of FIG. 11, which is arranged at an uppermost end, may extend in the first direction D1 without a change in conductivity type across the first cell 70a and the fourth cell 70d. Even when cells having different active region widths are adjacent to each other, active regions having the same conductivity type and the same width may extend in the first direction D1 in at least some regions, and thus, the seventh filler cell 70 may not extend to the at least some regions. Instead, a first additional cell 70′ and a second additional cell 70″ may be arranged in the at least some regions.

FIG. 11 shows only an example, and thus, either the first additional cell 70′ or the second additional cell 70″ may be formed. The configuration of the first and second additional cells 70′ and 70″ is not limited to the present specification, and as shown in the integrated circuit layout diagram 7000′ of FIG. 11, additional cells may be formed in a remaining space by flexibly adjusting the length of the seventh filler cell 70 in the second direction D2, thereby providing the degree of freedom to integrated circuit design.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. An integrated circuit comprising:
a first cell comprising a first active region and a second active region;
a second cell comprising a third active region and a fourth active region; and
a filler cell between the first cell and the second cell, and adjacent to the first cell and the second cell in a first direction, the filler cell having a one-pitch dimension,
wherein the filler cell comprises:
a first gate stack and a second gate stack that are adjacent to each other in the first direction; and
a separation structure between the first gate stack and the second gate stack, wherein the separation structure at least partially splits the first active region, the second active region, the third active region, and the fourth active region.

2. The integrated circuit of claim 1, wherein the separation structure comprises a nitride-based material.

3. The integrated circuit of claim 1, wherein
a first boundary between the filler cell and the first cell extends in a second direction intersecting with the first direction,
a second boundary between the filler cell and the second cell extends in the second direction,
the first gate stack is at the first boundary, and
the second gate stack is at the second boundary.

4. The integrated circuit of claim 1, wherein
the first cell comprises a first plurality of gate stacks extending from the first active region to the second active region in a second direction intersecting with the first direction,
the second cell comprises a second plurality of gate stacks extending from the third active region to the fourth active region in the second direction,
the first plurality of gate stacks are spaced apart from the first gate stack and the second gate stack in the first direction, and
the second plurality of gate stacks are spaced apart from the first gate stack and the second gate stack in the first direction.

5. The integrated circuit of claim 1, comprising a cell gate cut pattern extending along a boundary of the first cell, a boundary of the filler cell, and a boundary of the second cell.

6. The integrated circuit of claim 1, wherein the separation structure is absent of an oxide.

7. The integrated circuit of claim 1, comprising:
a p-type transistor on the first active region; and
an n-type transistor on the second active region.

8. An integrated circuit comprising:
a first cell comprising a first integrated transistor;
a second cell comprising a second integrated transistor;
a filler cell between the first cell and the second cell and adjacent to the first cell and the second cell in a first direction, the filler cell having a one-pitch dimension; and
a plurality of gate stacks extending in a second direction crossing the first direction and spaced apart from each other in the first direction,
wherein the filler cell comprises:
two gate stacks that are adjacent to each other among the plurality of gate stacks; and
a separation structure between the two gate stacks and extending in the second direction, and
wherein a first semiconductor pattern in the first cell and a second semiconductor pattern in the second cell are doped with impurities of different conductivity types, the first semiconductor pattern is adjacent to a first side wall of the separation structure, and the second semiconductor pattern is adjacent to a second side wall opposite to the first side wall of the separation structure.

9. The integrated circuit of claim 8, wherein the separation structure comprises a nitride-based material.

10. The integrated circuit of claim 8, wherein the first cell comprises a first active region and a p-type transistor on the first active region, and the second cell comprises a second active region and an n-type transistor on the second active region.

11. The integrated circuit of claim 8, comprising a cell gate cut pattern extending along a boundary of the first cell, a boundary of the filler cell, and a boundary of the second cell.

12. The integrated circuit of claim 8, wherein the separation structure is absent of an oxide.

13. An integrated circuit comprising:
a filler cell having a one-pitch dimension and comprising a first side wall and a second side wall opposite to the first side wall;
a first cell and a third cell that are adjacent to the first side wall of the filler cell;
a second cell adjacent to the second side wall of the filler cell; and
a plurality of gate stacks spaced apart from each other in a first direction and extending in a second direction crossing the first direction,
wherein the filler cell comprises:
two gate stacks that are adjacent to each other among the plurality of gate stacks; and
a separation structure between the two gate stacks and extending in the second direction,
wherein a height of the filler cell and a height of the second cell in the second direction are twice a height of the first cell and a height of the third cell in the second direction, respectively,
wherein the first cell and the third cell comprise a plurality of active regions having a first width in the second direction, and
wherein the second cell comprises a plurality of first active regions and a second active region, each first active region of the plurality of first active regions having the first width in the second direction, and the second active region having a second width that is twice the first width.

14. The integrated circuit of claim 13, wherein the separation structure comprises a nitride-based material.

15. The integrated circuit of claim 13, comprising a cell gate cut pattern at a boundary between the first cell and the third cell, wherein the cell gate cut pattern is away from the filler cell.

16. The integrated circuit of claim 13, wherein the separation structure comprises a first side wall and a second side wall opposite to the first side wall, and
wherein a first active region adjacent to the first side wall and a second active region adjacent to the second side wall have different widths in at least some regions.

17. The integrated circuit of claim 16, wherein a first semiconductor pattern adjacent to the first side wall of the separation structure and a second semiconductor pattern adjacent to the second side wall of the separation structure are doped with impurities of a same conductivity type.

18. The integrated circuit of claim 13, wherein the separation structure is absent of an oxide.

19. The integrated circuit of claim 13, wherein a height of the separation structure in the second direction is greater than a height of the first cell and a height of the third cell in the second direction.

20. The integrated circuit of claim 13, wherein a p-type transistor is on the plurality of first active regions, and an n-type transistor is on the second active region.
